(19) United States
(12) Patent Application Publication
(10) Pub. No.: US 2026/0371746 A1
(43) Pub. Date: Nov. 19, 2026

(54) SOLAR CELL, PREPARATION METHOD THEREFOR, AND PHOTOVOLTAIC MODULE

(71) Applicants: GCL SYSTEM INTEGRATION TECHNOLOGY CO., LTD., Suzhou (CN); WUHU GCL SYSTEM INTEGRATION NEW ENERGY TECHNOLOGY CO., LTD, Wuhu (CN)

(72) Inventors: Hang WENG, Suzhou (CN); Hua CAO, Suzhou (CN); Xiaofan JI, Suzhou (CN)

(21) Appl. No.: 19/712,055

(22) Filed: Jun. 18, 2026

Related U.S. Application Data
(63) Continuation of application No. PCT/CN2025/111024, filed on Jul. 28, 2025.

(30) Foreign Application Priority Data
May 14, 2025 (CN) 202510621900.6

(51) Int. Cl. H10F 19/35; H10F 19/33; H10F 77/70

(52) U.S. Cl. CPC H10F 19/35; H10F 19/33; H10F 77/707

(57) ABSTRACT

Provided are a solar cell, a preparation method therefor, and a photovoltaic module. The solar cell includes a substrate, a first functional structure, and a second functional structure. The substrate includes a front surface and a back surface opposite to the front surface. The back surface is divided into a first region, a second region, and a gap region. The first functional structure is disposed on the first region and includes a p-type doped layer. The second functional structure is disposed on the second region and includes an n-type doped layer. The gap region is configured to separate the first functional structure and the second functional structure. The substrate in the gap region has an arched convex structure in a direction from the front surface to the back surface.

### CROSS-REFERENCE TO RELATED APPLICATION

This application is a continuation application of International Application No. PCT/CN2025/111024, filed on Jul. 28, 2025, which claims priority to Chinese patent application No. 202510621900.6 filed on May 14, 2025, the entire contents of which are incorporated herein by reference.

### FIELD

The present disclosure relates to the field of solar cell technologies, and more particularly, to a solar cell, a preparation method therefor, and a photovoltaic module.

### BACKGROUND

In back-contact (BC) solar cells, both the positive and negative electrodes are printed on the back surface of the cells, leaving the front surface of the BC solar cells unshaded. Compared with conventional solar cells, the BC solar cells can achieve an approximately 7% increase in short-circuit current (Jsc). Currently, BC solar cells rely on the front surface to utilize incident photons, while the utilization rate of the gap region on the back surface is relatively low. Therefore, the utilization rate of sunlight by BC solar cells needs to be improved, and there is considerable room for enhancing the efficiency of BC solar cells.

### SUMMARY

The present disclosure aims to alleviate or solve at least one of the above-described problems to at least a certain extent.

In an aspect of the present disclosure, the present disclosure provides a solar cell. In some embodiments of the present disclosure, the solar cell includes a substrate, the substrate including a front surface and a back surface opposite to the front surface, the back surface being divided into a first region, a second region, and a gap region, a first functional structure disposed on the first region, the first functional structure including a p-type doped layer, and a second functional structure disposed on the second region. The second functional structure includes an n-type doped layer. The gap region is configured to separate the first functional structure and the second functional structure. The substrate in the gap region has an arched convex structure in a direction from the front surface to the back surface. The arched convex structure can increase a textured surface area of the gap region on the back surface and improve a light absorption capacity of the gap region. In addition, the arched convex structure can enable secondary utilization of light that passes through a gap of the solar cell and irradiates onto the ground, as well as scattered light from the ground, after being reflected by the ground, improving a light utilization rate of the solar cell and further improving an efficiency of the solar cell.

In some embodiments of the present disclosure, a height difference between a highest point and a lowest point of the arched convex structure ranges from 1.5 μm to 7 μm. In this way, the arched convex structure can significantly increase the textured surface area of the gap region on the back surface, further improving the light absorption capacity and light utilization rate of the solar cell.

In some embodiments of the present disclosure, a height difference between a surface of the p-type doped layer away from the substrate and the highest point of the arched convex structure is greater than or equal to 3 μm. In this way, the gap region can better isolate the first functional structure and the second functional structure, helping to further improve performance of the solar cell.

In some embodiments of the present disclosure, a height difference between a surface of the n-type doped layer away from the substrate and the highest point of the arched convex structure is greater than or equal to 1.5 μm. In this way, the gap region can better isolate the first functional structure and the second functional structure, helping to further improve the performance of the solar cell.

In another aspect of the present disclosure, the present disclosure provides a method for preparing a solar cell. In some embodiments of the present disclosure, the method includes: providing a substrate, the substrate including a front surface and a back surface opposite to the front surface, and dividing the back surface into a first region, a second region, and a gap region; forming a p-type doped layer and a borosilicate glass layer on the back surface; removing the borosilicate glass layer and the p-type doped layer from the second region and the gap region; forming an n-type doped layer and a phosphosilicate glass layer on the back surface; performing laser processing on structures on the first region and the gap region, laser energy applied to the gap region gradually decreasing and then gradually increasing along a width direction of the gap region; and performing wet texturing to remove the phosphosilicate glass layer, the n-type doped layer, and a portion of the substrate from the gap region, to cause the substrate in the gap region to form an arched convex structure. In this way, the degree of structural looseness in the gap region can be varied by laser processing, and the arched convex structure can be formed through subsequent wet texturing. The solar cell prepared by the method as described above has a high light utilization rate on the back surface of the solar cell, which is beneficial to improving the efficiency of the solar cell.

In some embodiments of the present disclosure, along the width direction of the gap region, laser processing is performed on different positions of the gap region using laser beams. Each of the laser beams has the same number of laser shots. Power of the laser beams at the different positions gradually decreases and then gradually increases. An overlap ratio between spots of any two laser beams is less than or equal to 5%. In this way, the degree of structural looseness in the gap region can be varied by adjusting the number of laser shots at the different positions, obtaining the arched convex structure through subsequent texturing.

In some embodiments of the present disclosure, along the width direction of the gap region, the number of laser shots at the different positions gradually decreases by a shots and then gradually increases by a shots, where a ranges from 1 to 5. In this way, a relatively smooth arched convex structure is formed, further increasing the textured surface area of the gap region and improving the light absorption capacity of the back surface.

In some embodiments of the present disclosure, the method satisfies at least one of the following conditions: energy of each laser beam applied to the gap region is less than or equal to 50 μj; an etching solution used for wet texturing includes sodium hydroxide and/or potassium hydroxide; and the arched convex structure has a plurality of pyramid structures. The plurality of pyramid structures has a size ranging from 1.5 μm to 1.8 μm and a height ranging from 0.6 μm to 1.2 μm.

In some embodiments of the present disclosure, the present disclosure provides a photovoltaic module. In some embodiments of the present disclosure, the photovoltaic module includes the solar cell as described above, or includes a solar cell prepared by the method as described above. In this way, the photovoltaic module possesses all the characteristics and advantages of the solar cell as described above, and thus details thereof will be omitted here. In summary, the photovoltaic module exhibits a high light utilization rate and efficiency.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 is a schematic structural diagram of a solar cell according to an embodiment of the present disclosure.

FIG. 2 is a schematic partial structural diagram of a solar cell according to an embodiment of the present disclosure.

FIG. 3 is a schematic partial structural diagram of a solar cell according to an embodiment of the present disclosure.

FIG. 4 is a schematic partial structural diagram of a solar cell according to an embodiment of the present disclosure.

FIG. 5 is a schematic partial structural diagram of a solar cell according to an embodiment of the present disclosure.

FIG. 6 is a schematic partial structural diagram of a solar cell according to an embodiment of the present disclosure.

### Reference Numerals of the Accompanying Drawings

10, substrate; 11, front surface; 12, back surface; A, first region; B, second region; C, gap region; 20, first functional structure; 21, first tunneling oxide layer; 22, p-type doped layer; 30, second functional structure; 31, second tunneling oxide layer; 32, n-type doped layer; 41, back passivation film; 42, back anti-reflection film; 51, pyramid structure.

### DETAILED DESCRIPTION OF THE EMBODIMENTS

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limit, the present disclosure.

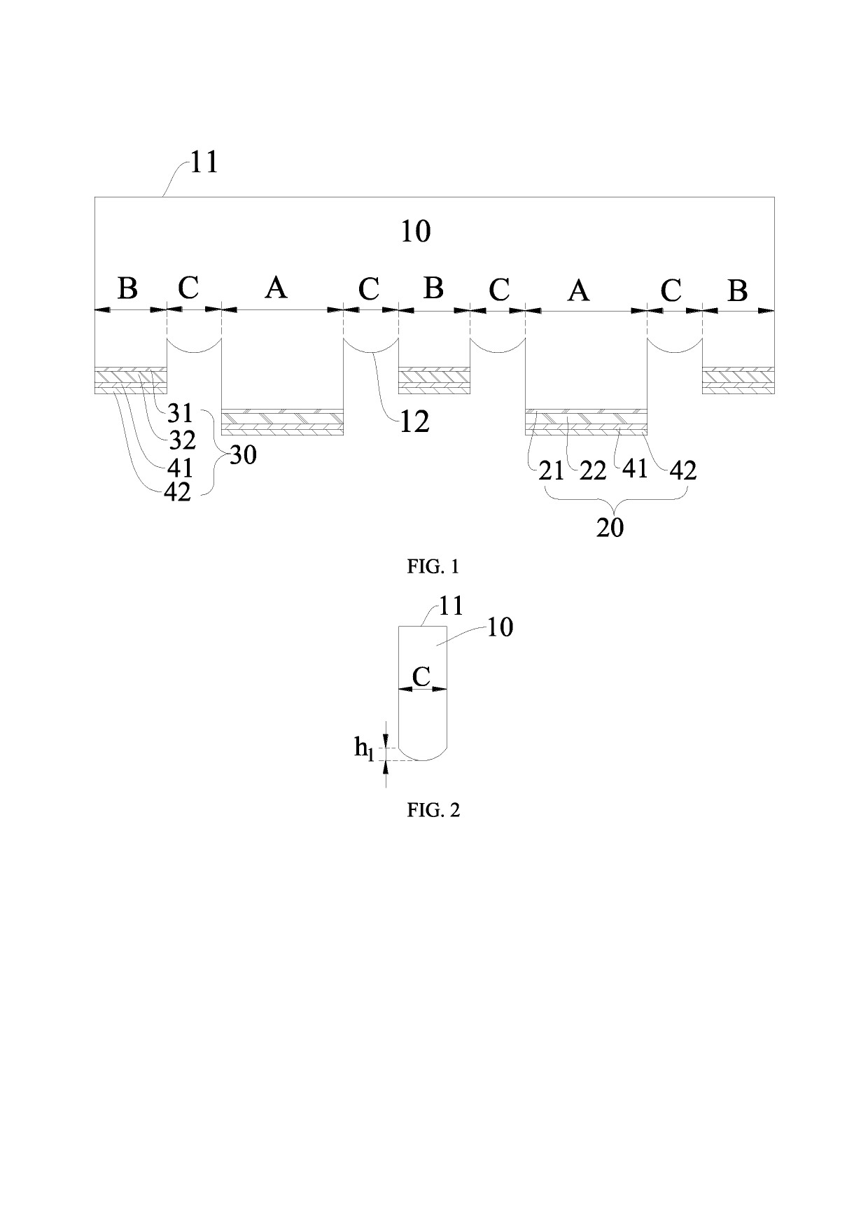

In an aspect of the present disclosure, the present disclosure provides a solar cell. In some embodiments of the present disclosure, as illustrated in FIG. 1, the solar cell includes a substrate 10, a first functional structure 20, and a second functional structure 30. The substrate 10 includes a front surface 11 and a back surface 12 opposite to the front surface 11. The back surface 12 is divided into a first region A, a second region B, and a gap region C. The first functional structure 20 is disposed on the first region A and includes a p-type doped layer 22. The second functional structure 30 is disposed on the second region B and includes an n-type doped layer 32. The gap region C is configured to separate the first functional structure 20 and the second functional structure 30. The substrate in the gap region C has an arched convex structure in a direction from the front surface 11 to the back surface 12.

A design of the arched convex structure can increase a textured surface area of the back surface and enhance a light absorption capacity of the solar cell. This arched convex structure can fully enable secondary utilization of light that passes through a gap of the solar cell and irradiates onto the ground, as well as scattered light from the ground, after being reflected by the ground, thereby helping to improve an efficiency and/or power of the solar cell.

In some embodiments of the present disclosure, the substrate 10 may be an n-type monocrystalline silicon wafer. In other embodiments of the present disclosure, the substrate 10 may be a p-type monocrystalline silicon wafer. A specific thickness of the substrate 10 is not particularly limited in the present disclosure, and can be selected and set by those skilled in the art as desired.

In some embodiments of the present disclosure, the substrate 10 has a minority carrier lifetime greater than 1 ms and a resistivity ranging from 0.5 Ω·cm to 2.1 Ω·cm.

In some embodiments, the p-type doped layer may be a boron-doped polycrystalline silicon layer, and the n-type doped layer may be a phosphorus-doped polycrystalline silicon layer.

In some embodiments of the present disclosure, the solar cell may be an IBC solar cell or a TBC solar cell.

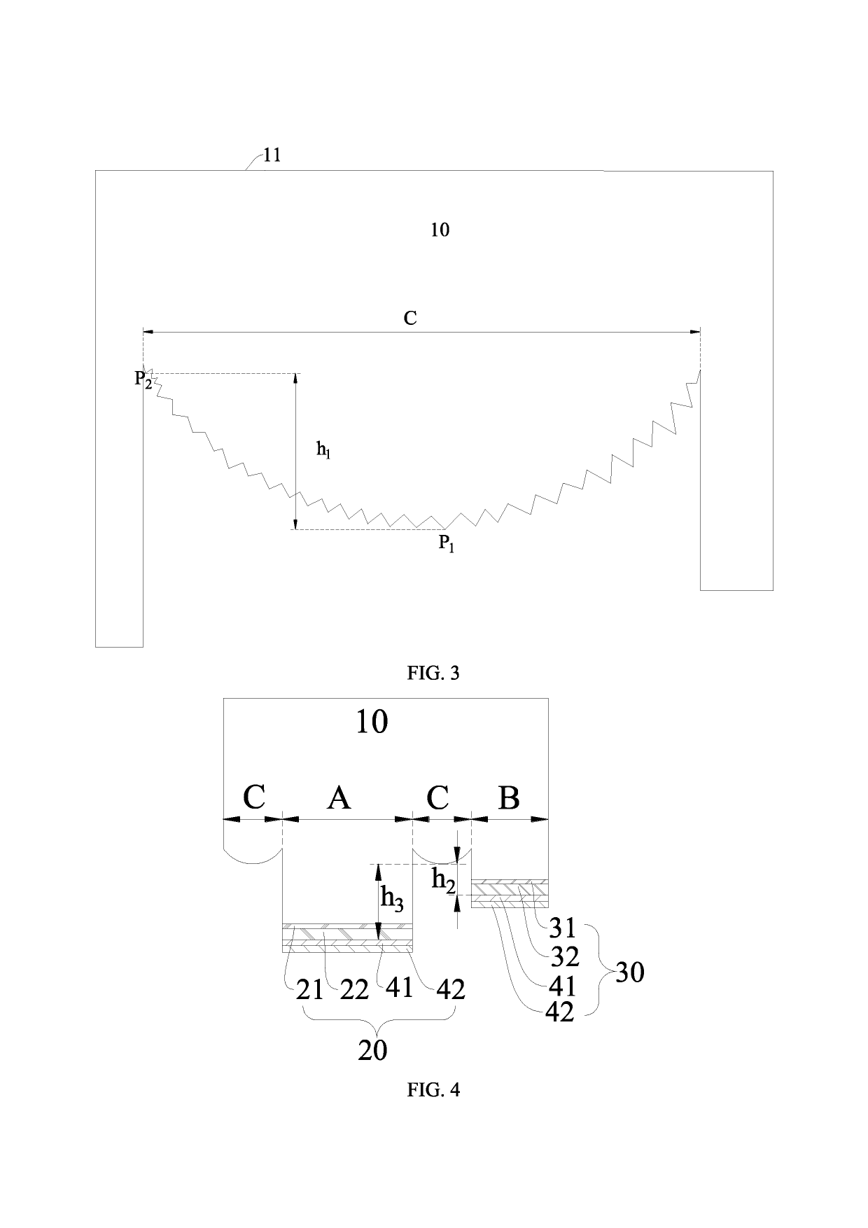

In some embodiments of the present disclosure, as illustrated in FIGS. 2 and 3, a height difference h₁ between a highest point P₁ and a lowest point P₂ of the arched convex structure may range from 1.5 μm to 7 μm. For example, the height difference h₁ between the highest point P₁ and the lowest point P₂ of the arched convex structure may be 1.5 μm, 1.8 μm, 2 μm, 2.5 μm, 3 μm, 4 μm, 5 μm, 6 μm, or 7 μm. It should be noted that, as illustrated in FIG. 3, the arched convex structure has a pyramidal textured surface. The highest point P₁ of the arched convex structure refers to a vertex of a pyramidal structure on the pyramidal textured surface that is at the greatest distance from the front surface 11 of the substrate 10, and the lowest point P₂ of the arched convex structure refers to a vertex of a pyramidal structure on the pyramidal textured surface that is at the smallest distance from the front surface 11 of the substrate 10. When the height difference between the highest point and the lowest point of the arched convex structure is within the above-described range, the textured surface area of the gap region can be significantly increased, which further improves the light absorption capacity of the solar cell, further enhancing a light utilization rate of the solar cell.

In some embodiments of the present disclosure, as illustrated in FIG. 4, a height difference h₃ between a surface of the p-type doped layer 22 away from the substrate 10 and the highest point of the arched convex structure may be greater than or equal to 3 μm. For example, the height difference h₃ between the surface of the p-type doped layer 22 away from the substrate 10 and the highest point of the arched convex structure may be 3 μm, 4 μm, 5 μm, 6 μm, 7 μm, or 8 μm. Therefore, there is a certain height difference between the arched convex structure and the p-type doped layer in the first functional structure, and the arched convex structure can provide a good isolation effect.

In some embodiments, the height difference h₃ between the surface of the p-type doped layer 22 away from the substrate 10 and the highest point of the arched convex structure may range from 3 μm to 8 μm.

In some embodiments of the present disclosure, as illustrated in FIGS. 1 and 4, the first functional structure 20 further includes a first tunneling oxide layer 21, and the p-type doped layer 22 is located on a side of the first tunneling oxide layer 21 away from the substrate 10.

In some embodiments, the first tunneling oxide layer 21 may be a silicon oxide layer.

In some embodiments, the first tunneling oxide layer 21 may have a thickness ranging from 1.5 nm to 2.5 nm.

In some embodiments, as illustrated in FIGS. 1 and 4, the first functional structure 20 may further include a back passivation film 41 located on a side of the p-type doped layer 22 away from the substrate 10. In some specific embodiments, the back passivation film 41 may be an aluminum oxide passivation film. In this way, a back surface defect structure can be passivated, carrier recombination can be reduced, and a photoelectric conversion efficiency of the solar cell can be improved.

In some embodiments of the present disclosure, as illustrated in FIGS. 1 and 4, the first functional structure 20 may further include a back anti-reflection film 42 located on the side of the p-type doped layer 22 away from the substrate 10. In some specific embodiments, the back anti-reflection film 42 may be a silicon nitride anti-reflection film. In this way, reflection of incident light can be reduced, which is beneficial to further improving the light utilization rate of the solar cell.

In some embodiments, as illustrated in FIGS. 1 and 4, the first functional structure may include the first tunneling oxide layer 21, the p-type doped layer 22, the back passivation film 41, and the back anti-reflection film 42. The back passivation film 41 is located on the side of the p-type doped layer 22 away from the substrate 10, and the back anti-reflection film 42 is located on a side of the back passivation film 41 away from the substrate 10.

In some embodiments of the present disclosure, the first functional structure may further include a first grid line in contact with the p-type doped layer.

In some embodiments, as illustrated in FIG. 4, a height difference h₂ between a surface of the n-type doped layer 32 away from the substrate 10 and the highest point of the arched convex structure may be greater than or equal to 1.5 μm. For example, the height difference h₂ between the surface of the n-type doped layer 32 away from the substrate 10 and the highest point of the arched convex structure may be 1.5 μm, 1.8 μm, 2 μm, 2.2 μm, 2.5 μm, 2.7 μm, 3 μm, or 3.5 μm. In some embodiments, the height difference h₂ between the surface of the n-type doped layer 32 away from the substrate 10 and the highest point of the arched convex structure may range from 1.5 μm to 3.5 μm.

In some embodiments of the present disclosure, as illustrated in FIGS. 1 and 4, the second functional structure 30 may further include a second tunneling oxide layer 31. The n-type doped layer 32 is located on a side of the second tunneling oxide layer 31 away from the substrate 10.

In some embodiments of the present disclosure, the second tunneling oxide layer 31 may be a silicon oxide layer.

In some embodiments of the present disclosure, the second tunneling oxide layer 31 may have a thickness ranging from 1.5 nm to 2.5 nm.

In some embodiments of the present disclosure, as illustrated in FIGS. 1 and 4, the second functional structure 30 may further include a back passivation film 41 located on a side of the n-type doped layer 32 away from the substrate 10.

In some embodiments of the present disclosure, as illustrated in FIGS. 1 and 4, the second functional structure 30 may further include a back anti-reflection film 42 located on the side of the n-type doped layer 32 away from the substrate 10.

In some embodiments of the present disclosure, as illustrated in FIGS. 1 and 4, in the direction from the front surface 11 to the back surface 12, the second functional structure 30 may further include the second tunneling oxide layer 31, the n-type doped layer 32, the back passivation film 41, and the back anti-reflection film 42 that are disposed sequentially.

In some embodiments of the present disclosure, the second functional structure 30 may further include a second grid line in contact with the n-type doped layer 32.

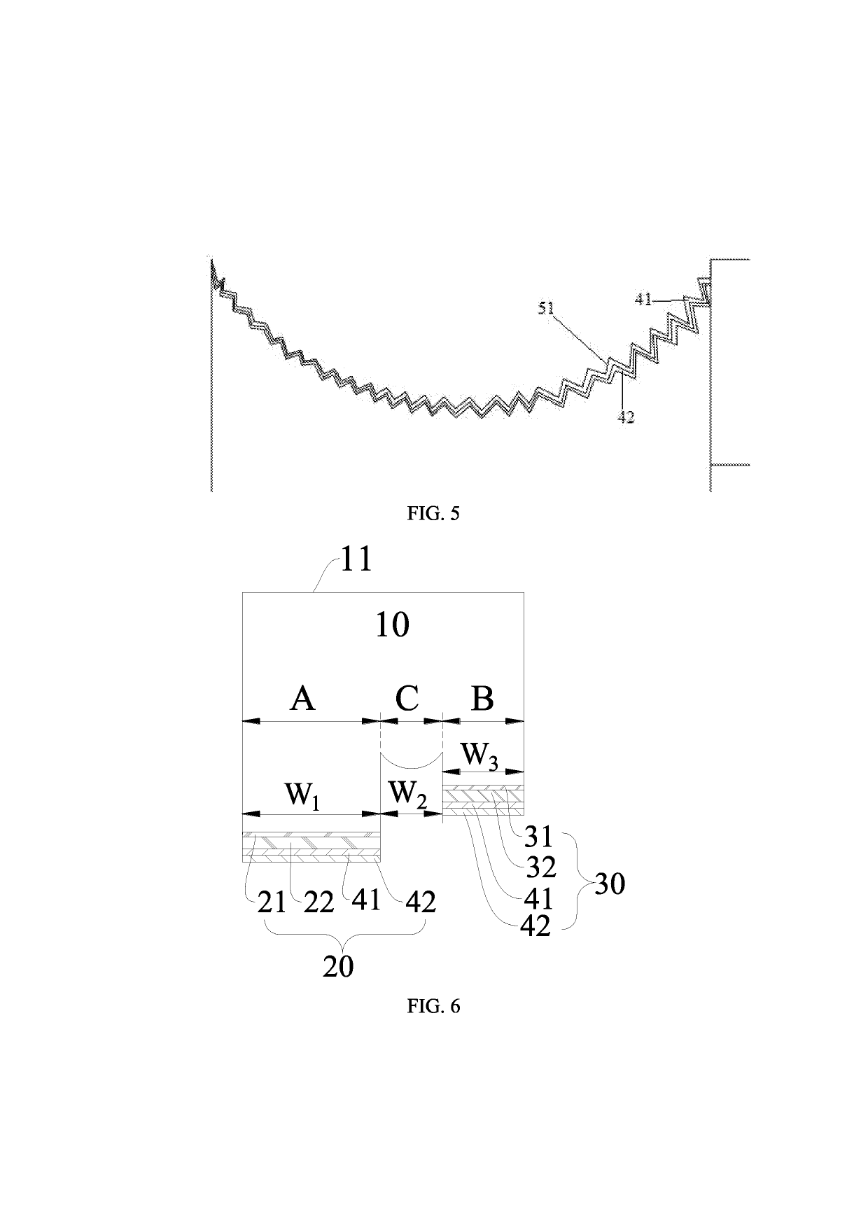

In some embodiments of the present disclosure, as illustrated in FIG. 5, the arched convex structure has a plurality of pyramid structures 51. The plurality of pyramid structures 51 may have a size ranging from 1.5 μm to 1.8 μm and a height ranging from 0.6 μm to 1.2 μm. For each of the plurality of pyramid structures 51, the size of the pyramid structure 51 refers to a maximum dimension of a base of the pyramid structure, and the height of the pyramid structure 51 refers to a distance between a vertex and the base of the pyramid structure. In some embodiments, the base of the pyramid structure is square or approximately square, and the maximum dimension of the base may be a length of a diagonal of the square.

In some embodiments of the present disclosure, as illustrated in FIG. 5, the back passivation film 41 and the back anti-reflection film 42 may be disposed on the gap region. The back passivation film 41 is located between the substrate and the back anti-reflection film 42. Each of the back passivation film 41 and the back anti-reflection film 42 on the gap region also has a textured surface.

In some embodiments of the present disclosure, as illustrated in FIG. 6, a width W₁ of the first region A may range from 300 μm to 500 μm. For example, the width W₁ of the first region A may be 300 μm, 350 μm, 400 μm, 450 μm, or 500 μm.

In some embodiments of the present disclosure, as illustrated in FIG. 6, a width W₃ of the second region B may range from 200 μm to 400 μm. For example, the width W₃ of the second region B may be 200 μm, 250 μm, 300 μm, 350 μm, or 400 μm.

In some embodiments of the present disclosure, as illustrated in FIG. 6, a width W₂ of the gap region C may range from 50 μm to 100 μm. For example, the width W₂ of the gap region C may be 50 μm, 60 μm, 70 μm, 80 μm, 90 μm, or 100 μm.

The width of the gap region ranges from approximately 50 μm to 100 μm, the width of the second region ranges from approximately 200 μm to 400 μm, and the width of the first region ranges from approximately 300 μm to 500 μm. The gap region accounts for approximately 6% of a total area. By forming the substrate of the gap region into the arched convex structure, the textured surface area of the gap region can be significantly increased. Therefore, the back surface of the substrate can be fully utilized, which improves a utilization rate of the incident light by the solar cell, thereby helping to enhance the efficiency of the solar cell.

In another aspect of the present disclosure, the present disclosure provides a method for preparing a solar cell. In some embodiments of the present disclosure, the method for preparing the solar cell may include the following operations.

At S10, a substrate is provided.

In some embodiments of the present disclosure, the substrate may be an n-type monocrystalline silicon wafer or a p-type monocrystalline silicon wafer.

In some embodiments of the present disclosure, the substrate includes a front surface and a back surface opposite to the front surface. The back surface is divided into a first region, a second region, and a gap region. A first functional structure having a p-type doped layer is disposed on the first region, a second functional structure having an n-type doped layer is disposed on the second region, and the gap region is configured to separate the first functional structure and the second functional structure.

Prior to preparing a tunneling oxide layer, the substrate may be cleaned and polished. In some embodiments, the substrate is cleaned and polished to remove slicing damage and surface contaminants from the n-type/p-type monocrystalline silicon substrate (101), forming a pyramidal base with a size ranging from 10 μm to 25 μm. The n-type/p-type monocrystalline silicon substrate has a minority carrier lifetime greater than 1 ms and a resistivity ranging from 0.5 Ω·cm to 2.1 Ω·cm.

At S20, a p-type doped layer and a borosilicate glass layer are formed on the back surface.

In some embodiments of the present disclosure, S20 may include the following operations S21 and S22.

At S21, a first tunneling oxide layer and an intrinsic polycrystalline silicon layer are formed on the back surface.

In some embodiments of the present disclosure, the first tunneling oxide layer may be grown on a surface of the substrate 101 by low-pressure chemical vapor deposition (LPCVD). A growth temperature may range from 550° C. to 650° C., a growth time may range from 5 min to 20 min, and a thickness of the first tunneling oxide layer may range from 1.5 nm to 2.5 nm.

In some embodiments of the present disclosure, the intrinsic polycrystalline silicon layer may be grown on a side of the first tunneling oxide layer away from the substrate by low-pressure chemical vapor deposition (LPCVD). The growth temperature may range from 550° C. to 650° C., the growth time may range from 3 min to 15 min, and the thickness of the intrinsic polycrystalline silicon layer may range from 150 nm to 400 nm.

In some embodiments of the present disclosure, the first tunneling oxide layer may not be formed, and the intrinsic polycrystalline silicon layer may be grown directly on the back surface of the substrate by LPCVD.

At S22, the p-type doped layer and the borosilicate glass layer were formed.

In some embodiments of the present disclosure, boron may be doped into the intrinsic polycrystalline silicon layer via high-temperature diffusion to form the p-type doped layer. A diffusion temperature may range from 800° C. to 900° C., and a diffusion time may range from 6 min to 12 min.

In some embodiments of the present disclosure, subsequent to forming the p-type doped layer, the borosilicate glass layer (boron-containing oxide layer, BSG) is formed on the p-type doped layer via post-oxidation. The temperature may range from 920° C. to 980° C., and the time may range from 25 min to 40min. The thickness of the borosilicate glass layer may range from 50 nm to 100 nm. The BSG is subsequently used as a mask to prepare for the subsequent laser process.

At S30, the borosilicate glass layer and the p-type doped layer are removed from the second region and the gap region.

In some embodiments of the present disclosure, S30 may include the following operations S31, S32, and S33.

At S31, laser grooving is performed.

In some embodiments, patterning can be performed on the second region and the gap region by a laser to remove BSG from the second region and the gap region.

In some embodiments of the present disclosure, patterned grooving can be performed on the BSG layer on the back surface of the substrate using a laser beam with energy ranging from 60 μj to 100 μj and a wavelength of 532 nm. In some embodiments, the groove may have a width ranging from 300 μm to 500 μm.

At S32, BSG is removed from the front surface of the substrate using a high-concentration HF acid solution in a chain machine. A concentration of the HF acid solution is in a range of 25% to 60%, a length of an acid tank is 4 m, and an operation speed ranges from 2.0 m/min to 3.0 m/min.

At S33, wet etching is performed to remove the residual borosilicate glass layer, p-type doped layer, and small portion of the substrate (removing 2 μm to 10 μm of the substrate) from a laser-grooved region on the back surface, forming a pyramidal base with a size ranging from 20 μm to 35 μm.

Through operations S31 to S33, the borosilicate glass layer and the p-type doped layer can be removed from the second region and the gap region, and the borosilicate glass layer and the p-type doped layer on the first region are retained.

When the first tunneling oxide layer is formed on the back surface, during the wet etching step, the residual borosilicate glass layer, p-type doped layer, the first tunneling oxide layer and small portion of the substrate (removing 2 μm to 10 μm of the substrate) are removed from the laser-grooved region on the back surface, and the first tunneling oxide layer and small portion of the substrate are removed from the front surface, forming the pyramidal base with the size ranging from 20 μm to 35 μm. Through operations S31 to S33, the borosilicate glass layer, the p-type doped layer, and the first tunneling oxide layer can be removed from the second region and the gap region, and the borosilicate glass layer, the p-type doped layer, and the first tunneling oxide layer on the first region can be retained.

At S40, an n-type doped layer and a phosphosilicate glass layer are formed on the back surface.

In some embodiments of the present disclosure, S40 may include the following operations S41 and S42.

At S41, the intrinsic polycrystalline silicon layer is formed on the back surface.

In some embodiments of the present disclosure, a second tunneling oxide layer may be grown on the back surface by LPCVD. A growth temperature may range from 550° C. to 650° C., a growth time may range from 5 min to 20 min, and a thickness of the second tunneling oxide layer may range from 1.5 nm to 2.5 nm.

In some embodiments of the present disclosure, the intrinsic polycrystalline silicon layer may be grown on a side of the second tunneling oxide layer away from the substrate by LPCVD. The growth temperature may range from 550° C. to 650° C., the growth time may range from 3 min to 15 min, and the thickness of the intrinsic polycrystalline silicon layer may range from 150 nm to 400 nm.

In other embodiments of the present disclosure, the second tunneling oxide layer may not be formed, and the intrinsic polycrystalline silicon layer may be grown directly on a side of the substrate by LPCVD.

At S42, the n-type doped layer and the phosphosilicate glass layer are formed.

In some embodiments of the present disclosure, phosphorus may be doped into the intrinsic polycrystalline silicon layer via high-temperature diffusion to form the n-type doped layer. A diffusion temperature may range from 800° C. to 900° C., and a diffusion time may range from 20 min to 30 min.

In some embodiments of the present disclosure, subsequent to forming the n-type doped layer, the phosphosilicate glass layer (phosphorus-containing oxide layer, PSG) is formed on the n-type doped layer via post-oxidation. The temperature may range from 900° C. to 950° C., and the time may range from 20 min to 40 min. The thickness of the phosphosilicate glass layer may range from 30 nm to 60 nm. The PSG is subsequently used as a mask to prepare for the subsequent laser process.

At S50, laser processing is performed on structures on the first region and the gap region. Laser energy applied to the gap region gradually decreases and then gradually increases along a width direction of the gap region.

The laser energy applied to the gap region gradually decreases and then gradually increases along the width direction of the gap region, causing a degree of looseness of the structure in the gap region to gradually decrease and then gradually increase along the width direction. In the subsequent wet texturing process, the structure with smaller degree of looseness reacts more slowly with the etching solution and etched to a smaller depth, while the structure with larger degree of looseness reacts more quickly with the etching solution and etched to a larger depth. In this way, an arched convex structure having a thickness that first gradually increases and then gradually decreases can be obtained.

In some embodiments of the present disclosure, in the first region, patterned grooving can be performed on the BSG layer on the back surface of the substrate by a laser beam with an energy ranging from 60 μj to 100 μj and a wavelength of 532 nm. The groove may have a width ranging from 300 μm to 500 μm.

In the present disclosure, the laser energy applied to the gap region can be gradually decreased and then gradually increased along the width direction of the gap region by different methods.

In some embodiments of the present disclosure, during the laser processing of the structure of the gap region, along the width direction of the gap region, laser processing is performed on different positions of the gap region using laser beams. Each of the laser beams has the same number of laser shots, power of the laser beams at the different positions gradually decreases and then gradually increases, and an overlap ratio between spots of any two laser beams is less than or equal to 5%. Different power of the laser beams at the different positions results in different energy of the laser beams and different degrees of structural looseness in different regions subsequent to processing. Higher power corresponds to higher energy, resulting in a looser structure subsequent to the processing. The overlap ratio between the spots of any two laser beams is less than or equal to 5%, in such a manner that final morphology of the gap region can be better controlled, obtaining a relatively smooth arched convex structure. In some embodiments, the overlap ratio between the spots of any two laser beams may range from 0% to 5%. For example, the overlap ratio may be 0%, 0.5%, 0.8%, 1%, 1.2%, 1.5%, 2%, 2.5%, 3%, 3.5%, 4%, 4.5%, or 5%.

In some specific embodiments, along the width direction of the gap region, the laser processing is performed on different positions of the gap region using the laser beams. Each of the laser beams has the same number of laser shots, and the power of the laser beams at the different positions starts at 50 μj, gradually decreases with a gradient difference of 2 μj, and then gradually increases to 50 μj with a gradient difference of 2 μj. The overlap ratio between the spots of any two laser beams is less than or equal to 5%.

In other embodiments of the present disclosure, during the laser processing of the structure of the gap region, along the width direction of the gap region, laser processing is performed on different positions of the gap region using laser beams. Each of the laser beams has the same power (same energy), the number of laser shots at the different positions gradually decreases and then gradually increases, and an overlap ratio between spots of any two laser beams is less than or equal to 5%. The laser beam has the same power, but the number of laser shots at the different positions is different, resulting in different degrees of structural looseness in different regions subsequent to processing. The structure subsequent to processing becomes looser as the number of laser shots increases. The overlap ratio between the spots of any two laser beams is less than or equal to 5%, in such a manner that final morphology of the gap region can be better controlled, obtaining a relatively smooth arched convex structure. In some embodiments, the overlap ratio between the spots of any two laser beams may range from 0% to 5%. For example, the overlap ratio may be 0%, 0.5%, 0.8%, 1%, 1.2%, 1.5%, 2%, 2.5%, 3%, 3.5%, 4%, 4.5%, or 5%.

In some specific embodiments of the present disclosure, each of the laser beams has the same power. Along the width direction of the gap region, the number of laser shots at different positions gradually decreases by a shots and then gradually increases by a shots, where a ranges from 1 to 5. For example, a may be 1, 2, 3, 4, or 5.

In some specific embodiments, the power of the laser beams remains unchanged, and the spots of the laser beams move along the width direction of the gap region (from left to right or from right to left). A spot of the first laser beam shoots n times, a spot of the second beam shoots (n-1) times, and an overlap ratio between the spots of the two laser beams is 0%, and so on, until a spot of the laser beam at a middle position of the gap region shoots only once. The spots of the laser beams continue to move rightward/leftward, and the number of repeated laser shots gradually increases until reaching the other side of the gap region.

In some embodiments of the present disclosure, energy of each laser beam applied to the gap region is less than or equal to 50 μj, which is more conducive to controlling the degree of looseness of the structure of the gap region subsequent to laser processing. As a result, a relatively smooth arched convex structure can be obtained subsequent to wet texturing.

In some specific embodiments, the power of the laser beams remains unchanged, the energy of the laser beams is 40 μj, and the spots of the laser beams move along the width direction of the gap region. A spot of the first laser beam shoots n times, a spot of the second laser beam shoots (n-1) times, and the overlap ratio between the spots of the two laser beams is 0%, and so on, until a spot of the laser beam at the middle position of the gap region shoots only once. The spots of the laser beams continue to move rightward/leftward, and the number of repeated laser shots gradually increases until reaching the other side of the gap region.

At S60, wet texturing is performed to remove the phosphosilicate glass layer, the n-type doped layer, and a portion of the substrate from the gap region, to cause the substrate in the gap region to form an arched convex structure.

The wet texturing is performed to remove the residual phosphosilicate glass layer, n-type doped layer, and portion of the substrate (with a thickness ranging from 2 μm to 10 μm) from the gap region, and the n-type doped layer from the front surface. Pyramid structures (anisotropic) are formed on the front surface of the substrate and the gap region on the back surface of the substrate. In some embodiments, the pyramid structures may have a size ranging from 1.5 μm to 1.8 μm and a height ranging from 0.6 μm to1.2 μm.

In some embodiments of the present disclosure, when the second tunneling oxide layer is disposed between the n-type doped layer and the substrate, the wet texturing can remove the residual phosphosilicate glass layer, n-type doped layer, second tunneling oxide layer, and portion of the substrate (with the thickness ranging from 2 μm to 10 μm) from the gap region, and the n-type doped layer and the second tunneling oxide layer from the front surface, and form the pyramid structures (anisotropic) on the front surface of the substrate and the gap region on the back surface of the substrate.

In some embodiments of the present disclosure, the wet texturing may involve pre-cleaning, followed by etching, and finally post-cleaning.

In some embodiments of the present disclosure, a cleaning solution used for pre-cleaning may be prepared at a volume ratio of alkaline solution to hydrogen peroxide of 1:2 to 5. A pre-cleaning temperature may range from 60° C. to 70° C., and a pre-cleaning time may range from 60 s to 300 s. Alkali in the alkaline solution may include NaOH and/or KOH.

In some embodiments of the present disclosure, an etching process is performed subsequent to pre-cleaning. An etching solution used for the etching process may be prepared at a volume ratio of additive to alkaline solution of 1:2 to 4. An etching temperature may range from 65° C. to 85° C., and an etching time may range from 100 s to 500 s. The alkali in the alkaline solution may include NaOH and/or KOH. In the present disclosure, the additive is a commercially available additive. The additive and can complex with residual phosphorus oxides on the surface, slowing down the reaction rate. The reaction rate becomes slower as the residual phosphorus oxides increase. By controlling different thicknesses of PSG in a laser opening region, the texturing speed at different positions of the gap region is controlled, ultimately forming the arched convex structure.

In some embodiments of the present disclosure, subsequent to the etching process, a post-cleaning is performed. A cleaning solution used for the post-cleaning can be prepared at a volume ratio of alkaline solution to hydrogen peroxide of 1:2 to 5. A post-cleaning temperature may range from 60° C. to 70° C., and a post-cleaning time may range from 60 s to 300 s. The alkali in the cleaning solution used for the post-cleaning may include NaOH and/or KOH.

In some embodiments of the present disclosure, subsequent to forming the arched convex structure by wet texturing, preparation of the solar cell further includes removing the borosilicate glass layer from the first region and the phosphosilicate glass layer from the second region using an HF acid solution.

In some embodiments of the present disclosure, the preparation of the solar cell further includes: forming a front passivation film and a back passivation film; forming a front anti-reflection film and a back anti-reflection film; and printing back electrodes (a first grid line and a second grid line) and sintering to form an electrode system.

In some embodiments, each of the front passivation film and the back passivation film may each independently include an aluminum oxide passivation film. In some embodiments, each of the front anti-reflection film and the back anti-reflection film may each independently include a silicon nitride anti-reflection film.

In another aspect of the present disclosure, the present disclosure provides a photovoltaic module. In some embodiments of the present disclosure, the photovoltaic module may include the solar cell as described above, or the photovoltaic module may include a solar cell prepared by the method as described above. In this way, the photovoltaic module possesses all the features and advantages of the solar cell as described above, and thus details thereof will be omitted here. In general, the photovoltaic module has a high light absorption capacity and a high utilization rate of incident light.

In some embodiments of the present disclosure, the photovoltaic module may include a plurality of solar cells.

The present disclosure is described below through specific embodiments. It should be understood by those skilled in the art that the specific embodiments below are merely illustrative and do not limit the scope of the present disclosure in any way. In addition, in the following embodiments, unless otherwise specified, all materials and equipment used are commercially available. If specific processing conditions and methods are not explicitly described in the subsequent embodiments, the processing may be performed under conditions and methods well known in the art.

### Example 1

(1) An N-type monocrystalline silicon wafer was used as the substrate. The substrate was cleaned and polished to remove substrate slicing damage and surface contaminants, forming a pyramidal base.

The substrate included a front surface and a back surface. The back surface can be divided into a first region, a second region, and a gap region. A first functional structure with a p-type doped layer was disposed on the first region, a second functional structure with an n-type doped layer was disposed on the second region, and the gap region was configured to separate the first functional structure and the second functional structure.

(2) A first tunneling oxide layer (silicon oxide) was grown on the surface of the substrate by LPCVD at a growth temperature of 600° C. for a growth time of 10 min.

An intrinsic polycrystalline silicon layer was grown on a side of the first tunneling oxide layer away from the substrate by LPCVD at a growth temperature of 600° C. for a growth time of 5 min.

(3) Boron diffusion was performed to dope the intrinsic polycrystalline silicon layer with boron to form a p-type doped layer (boron-doped polycrystalline silicon layer). A diffusion temperature was 850° C. and a diffusion time was 8 min. BSG was formed by post-oxidation at a temperature of 950° C. for 30 min.

(4) Laser Grooving: Patterned grooving was performed on the back BSG using a laser beam with a wavelength of 532 nm. Laser-irradiated regions were the second region and the gap region.

(5) The front BSG was removed using a high-concentration HF acid solution in a chain machine. A concentration of the HF acid solution was 40%, a length of the acid tank was 4 m, and the operation speed was 2.5 m/min.

(6) Wet etching was performed to remove the residual borosilicate glass layer, p-type doped layer, first tunneling oxide layer, and small portion of substrate from the laser-grooved region on the back surface in step (4), and the first tunneling oxide layer and small portion of the substrate from the front surface, forming a pyramidal base.

(7) A second tunneling oxide layer (silicon oxide) was grown on the back surface by LPCVD at a growth temperature of 600° C. for a growth time of 10 min.

The intrinsic polycrystalline silicon layer was grown on the side of the second tunneling oxide layer away from the substrate by LPCVD at a growth temperature of 600° C. for a growth time of 8 min.

(8) Phosphorus diffusion was performed to dope the intrinsic polycrystalline silicon layer with phosphorus, forming an n-type doped layer (phosphorus-doped polycrystalline silicon layer). The diffusion temperature was 850° C., and the diffusion time was 25 min. PSG was formed by post-oxidation at a temperature of 930° C. for 30 min.

(9) Laser Grooving: Laser grooving was performed on the first region and the gap region to remove PSG.

For the first region, the first region was irradiated with a laser beam having a wavelength of 532 nm to remove the PSG in this region.

For the gap region, laser processing was performed using a laser beam with energy of 50 μj laser beam from left to right along the width direction of the gap region. A spot of the first laser beam shot n times, a spot of the second laser beam shot (n-1) times, where n was in a range of 3 to 8. An overlap ratio between the spots of the two laser beams was 0%, and so on, until a spot of the laser beam at a middle position shot only once. Continuing to move rightward, the number of laser shots increased sequentially (incremented by one for each rightward movement) until reaching the other side of the gap region.

(10) The front PSG was removed using the high-concentration HF acid solution in the chain machine. The concentration of the HF acid solution was 20%, the length of the acid tank was 2 m, and the operation speed was 4.3 m/min.

(11) Wet Texturing: A cleaning solution was prepared at a volume ratio of alkaline solution to hydrogen peroxide of 1:2 for pre-cleaning the cell. The pre-cleaning was performed at a temperature of 65° C. for 100 s. The alkali used was NaOH. An etching solution was prepared at a volume ratio of additive to alkaline solution of 1:3 for the etching process. The etching process was performed at a temperature of 75° C. for 200 s. The alkali used was NaOH. A cleaning solution was prepared at a volume ratio of alkaline solution to hydrogen peroxide of 1:2 for post-cleaning the cell. The post-cleaning was performed at a temperature of 65° C. for 100 s. The alkali used was NaOH.

Through the wet texturing, the residual phosphosilicate glass layer, n-type doped layer, second tunneling oxide layer, and small portion of substrate were removed from the laser-grooved region in step (9), and the n-type doped layer and the second tunneling oxide layer were removed from the front surface were removed by wet texturing, and a pyramid structure (anisotropic) was formed on the substrate.

(12) An HF acid solution was used to remove the borosilicate glass layer on the first region and the phosphosilicate glass layer on the second region.

(13) An aluminum oxide passivation film was deposited on the front surface and the back surface.

(14) A silicon nitride anti-reflection film was deposited on the front surface and the back surface.

(15) Electrode printing and sintering were performed on the back surface to form an electrode system, obtaining a solar cell.

### Example 2

A difference from Example 1 was that, in step (9) of Example 2, a laser beam with an energy of 40 μj was used to perform laser grooving on the gap region. The remaining steps and parameters were consistent with those in Example 1.

### Example 3

A difference from Example 1 was that, in step (9) of Example 3, when laser grooving was performed on the gap region, the number of laser shots at two adjacent positions differed by 3 times, while the spot of the laser beam at the middle position still shot only once. The remaining steps and parameters were consistent with those in Example 1.

### Example 4

A difference from Example 1 was that, in step (9) of Example 4, when laser grooving was performed on the gap region, the number of laser shots at two adjacent positions differed by 5 times, while the spot of the laser beam at the middle position still shot only once. The remaining steps and parameters were consistent with those in Example 1.

### Example 5

A difference from Example 1 was that, in step (9) of Example 5, when laser grooving was performed on the gap region, the spot of the laser beam at the middle position shot only once, and an overlap ratio between spots of two adjacent laser beams was 2%. The remaining steps and parameters were consistent with those in Example 1.

### Example 6

A difference from Example 1 was that, in step (9) of Example 6, when laser grooving was performed on the gap region, the spot of the laser beam at the middle position shot only once, and an overlap ratio between spots of two adjacent laser beams was 5%. The remaining steps and parameters were consistent with those in Example 1.

### Example 7

A difference from Example 1 was that steps of laser grooving on the gap region were as follows: along the width direction of the gap region, each of the laser beams shot 10 times, energy of the spot of the first laser beam was 50 μj, energy of the spot of the second laser beam was 45 μj, and an overlap ratio between spots of the two adjacent laser beams was 0%. By analogy, energy of the spot of the laser beam at the middle position was the lowest. Continuing to move rightward, the energy of the laser beams increased sequentially (incremented by 5 uj for each rightward movement) until reaching the other side of the gap region. The remaining steps and parameters were consistent with those in Example 1.

In each example, by adjusting the parameters of laser grooving on the gap region in step (9), the structural looseness of the gap region can be gradually decreased and then gradually increased along the width direction of the gap region subsequent to the laser grooving. During wet texturing, the looser the structure, the faster the etching solution reacts with the structure, ultimately forming the arched convex structure. The arched convex structure can significantly increase the textured surface area on the back surface and improve the light absorption capacity of the solar cell, improving the cell efficiency.

In the description of the present disclosure, the orientation or the position indicated by terms such as “front” and “back” should be construed to refer to the orientation or the position as shown in the drawings, and is only for the convenience of describing the present disclosure, rather than requiring that the present disclosure must be constructed and operated in a specific orientation, and therefore cannot be understood as a limitation of the present disclosure.

Reference throughout this specification to “an embodiment”, “some embodiments”, or “other embodiments” means that a particular feature, structure, material, or characteristic described in connection with the embodiment is included in at least one embodiment or example of the present disclosure. In this specification, exemplary descriptions of aforesaid terms are not necessarily referring to the same embodiment or example. Further, the particular features, structures, materials, or characteristics can be combined in any suitable manner in one or more embodiments or examples. In addition, different embodiments or examples and features of different embodiments or examples described in the specification may be combined by those skilled in the art without mutual contradiction. Furthermore, it should be noted that in the present specification, terms “first” and “second” are only used for descriptive purposes, and cannot be understood as indicating or implying relative importance or implicitly indicating the number of indicated technical features.

Although the embodiments of the present disclosure have been illustrated and described above, it will be understood by those of ordinary skill in the art that the above embodiments are exemplary only and should not be construed as limiting the scope of the invention. Modifications, alterations, substitutions, and variations can be made to the described embodiments without departing from the scope of the present disclosure.

What is claimed is:

1. A solar cell, comprising:
a substrate, wherein the substrate comprises a front surface and a back surface opposite to the front surface, the back surface being divided into a first region, a second region, and a gap region,
a first functional structure disposed on the first region, the first functional structure comprising a p-type doped layer;
a second functional structure disposed on the second region, the second functional structure comprising an n-type doped layer,
wherein the gap region is configured to separate the first functional structure and the second functional structure, and
wherein the substrate in the gap region has an arched convex structure in a direction from the front surface to the back surface.

2. The solar cell according to claim 1, wherein a height difference between a highest point and a lowest point of the arched convex structure ranges from 1.5 μm to 7 μm.

3. The solar cell according to claim 1, wherein a height difference between a surface of the p-type doped layer away from the substrate and a highest point of the arched convex structure is greater than or equal to 3 μm.

4. The solar cell according to claim 1, wherein a height difference between a surface of the n-type doped layer away from the substrate and a highest point of the arched convex structure is greater than or equal to 1.5 μm.

5. A method for preparing the solar cell according to claim 1, the method comprising:
providing a substrate, wherein the substrate comprises a front surface and a back surface opposite to the front surface, and dividing the back surface into a first region, a second region, and a gap region;
forming a p-type doped layer and a borosilicate glass layer on the back surface;
removing the borosilicate glass layer and the p-type doped layer from the second region and the gap region;
forming an n-type doped layer and a phosphosilicate glass layer on the back surface;
performing laser processing on structures on the first region and the gap region, wherein laser energy applied to the gap region gradually decreases and then gradually increases along a width direction of the gap region; and
performing wet texturing to remove the phosphosilicate glass layer, the n-type doped layer, and a portion of the substrate from the gap region, to cause the substrate in the gap region to form an arched convex structure.

6. The method according to claim 5, wherein along the width direction of the gap region, laser processing is performed on different positions of the gap region using laser beams, each of the laser beams having the same number of laser shots, power of the laser beams at the different positions gradually decreasing and then gradually increasing, and an overlap ratio between spots of any two laser beams being less than or equal to 5%.

7. The method according to claim 5, wherein along the width direction of the gap region, laser processing is performed on different positions of the gap region using laser beams, each of the laser beams having the same power, the number of laser shots at the different positions gradually decreasing and then gradually increasing, and an overlap ratio between spots of any two laser beams being less than or equal to 5%.

8. The method according to claim 7, wherein along the width direction of the gap region, the number of laser shots at the different positions gradually decreases by a shots and then gradually increases by a shots, where a ranges from 1 to 5.

9. The method according to claim 5, satisfying at least one of the following conditions:
energy of each laser beam applied to the gap region is less than or equal to 50 μj;
an etching solution used for wet texturing comprises sodium hydroxide and/or potassium hydroxide; and
the arched convex structure has a plurality of pyramid structures, wherein the plurality of pyramid structures has a size ranging from 1.5 μm to 1.8 μm and a height ranging from 0.6 μm to 1.2 μm.

10. A photovoltaic module, comprising a solar cell, wherein the solar cell comprises:
a substrate, wherein the substrate comprises a front surface and a back surface opposite to the front surface, the back surface being divided into a first region, a second region, and a gap region,
a first functional structure disposed on the first region, the first functional structure comprising a p-type doped layer;
a second functional structure disposed on the second region, the second functional structure comprising an n-type doped layer,
wherein the gap region is configured to separate the first functional structure and the second functional structure, and
wherein the substrate in the gap region has an arched convex structure in a direction from the front surface to the back surface.

11. The photovoltaic module according to claim 10, wherein a height difference between a highest point and a lowest point of the arched convex structure ranges from 1.5 μm to 7 μm.

12. The photovoltaic module according to claim 10, wherein a height difference between a surface of the p-type doped layer away from the substrate and a highest point of the arched convex structure is greater than or equal to 3 μm.

13. The photovoltaic module according to claim 10, wherein a height difference between a surface of the n-type doped layer away from the substrate and a highest point of the arched convex structure is greater than or equal to 1.5 μm.
